(19) United States
(12) Patent Application Publication
(10) Pub. No.: US 2005/0151131 A1
(43) Pub. Date: Jul. 14, 2005

(54) Polycrystalline thin-film solar cells

(76) Inventors: John F Wager III, Corvallis, OR (US); Douglas A. Keszler, Corvallis, OR (US)

Correspondence Address: KLARQUIST SPARKMAN, LLP, 121 SW SALMON STREET, SUITE 1600, PORTLAND, OR, 97204, US

(21) Appl. No.: 10/517,728

(22) PCT Filed: Jun. 10, 2003
(86) PCT No.: PCT/US03/18211

Related U.S. Application Data
(60) Provisional application No. 60/387,706, filed on Jun. 11, 2002.

(51) Int. Cl. H01L 29/04; H01L 21/00

(52) U.S. Cl. 257/51; 438/60; 257/183

(57) ABSTRACT

Double heterojunction polycrystalline thin-film solar cell devices that include a polycrystalline p-layer, a polycrystalline i-layer, and a polycrystalline n-layer. In one variant, at least two of the p-layer, i-layer, and n-layer comprise a polycrystalline Cu material. In another variant, each of the p-layer, i-layer, and n-layer comprise a common cation or a common anion.

### PRIORITY CLAIM

This application claims benefit of U.S. Provisional Application 60/387,706, filed Jun. 11, 2002, and incorporated herein by reference.

### FIELD

The present disclosure relates to a semiconductor solar cell.

### BACKGROUND

Potential shortages and global-warming issues associated with the use of fossil fuels have focused attention on the need for alternate sources of energy to generate electricity. Among the energy sources now in use for this purpose, only nuclear energy is generally considered as a possible alternative to fossil fuels. Issues relating to the inherent risks to life and property involved in operating nuclear reactors, as well as in the disposal of the radioactive waste have raised questions as to the viability of nuclear power as a preferred energy source.

For these and other reasons, the wind and the sun are considered possible sources of energy for use in driving electrical turbines and generators. Both of these renewable energy sources, however, remain only in the experimental stages despite the extensive study that has been given to their development and potential use. Both, in their present state of development are incapable of providing sufficient amounts of electrical energy at costs that are competitive with presently used sources of energy.

A device that is known to have the capability of transforming the sun's energy into electrical energy is a semiconductor solar cell. The arrangement of large arrays of solar cells, preferably in areas having a plentiful supply of sunlight, is very appealing for generating electricity.

Early solar cell technology dates to 1941 when Russell Ohl invented a silicon solar cell. An early solar cell consisted of a semiconductor wafer which constituted a single crystal, usually of silicon The thickness of the silicon wafer was approximately in the range of about 200-500 microns. Such a wafer included a relatively narrow semiconductor window region of one conductivity type, on which the light energy was incident, and formed on a relatively thick collector region of an opposite conductivity type and of a lower impurity concentration than the window region.

There have been many attempts to provide economical, simple, dry, and controllable thin-film solar cells. Currently, the single heterojunction devices comprised of CdS/CuInₓGa₁₋ₓSe₂ and CdS/CdTe are the two most efficient thin film solar cells and which appear to have commercial viability, as discussed in the book entitled Clean Electricity from Photovoltaics by Archer and Hill and published by Inperial College Press.

A need continues to exist for a commercially viable solar cell.

### SUMMARY

Disclosed herein are p-i-n double-heterojunction polycrystalline thin-film solar cell devices. In one variant, the thin-film solar cell includes a polycrystalline p-layer, a polycrystalline i-layer, and a polycrystalline n-layer, wherein at least two of the player, i-layer, and n-layer comprise a polycrystalline Cu material. In another variant, each of the p-layer, i-layer, and n-layer comprise a common cation or a common anion.

### BRIEF DESCRIPTION OF THE DRAWING

FIG. 1 is a schematic drawing of an idealized energy-band diagram for a pin double-heterojunction polycrystalline thin-film solar cell;

FIG. 2 is a schematic sectional view of a first example of the presently disclosed solar cell structure; and

FIG. 3 is a schematic sectional view of a second example of the presently disclosed solar cell structure.

Like reference numerals refer to like elements in the figures unless indicated otherwise.

### DETAILED DESCRIPTION OF SEVERAL EXAMPLES

More detailed description of the following terms are provided solely for the benefit of the reader, and should not be construed to limit the terms to any specific examples provided. They should also not be construed to be narrower than those accepted by persons of ordinary skill in the art.

“Reflector” will mean either an energy barrier in the conduction band at the i-layer/p-layer interface to suppress electron injection into the p-layer or an energy barrier in the valence band at the n-layer/i-layer interface to suppress hole injection into the n-layer.

“Conduction band” will define a band in which electrons can move freely in a solid, producing a net transport of charge. The conduction band may be the lowest unoccupied energy band in a material.

“Hole” will refer to a deficiency in valence electrons. In certain examples, holes may be created by impurities added to an intrinsic semiconductor, producing a p-type material.

“Valence band” will define a band in which holes can move freely in a solid, producing a net transport of charge. The valence band may be the highest occupied energy band.

“Doping” will refer to the addition of small amounts of foreign species (e.g., atoms, ions, etc.) into the molecular structure (e.g., crystal lattice) of a semiconductor to achieve a desired characteristic, as in the production of an n-type or a p-type material. An n-type semiconductor has at least one donor impunity incorporated into it that contributes free electrons; a p-type semiconductor has at least one acceptor impurity incorporated into it, producing ‘holes’, or electron deficiencies.

“Drift” will be used when electrons and/or holes move as a consequence of an applied voltage, and leads to the flow of current.

The “Fermi level” is the electrochemical potential that determines the electronic state occupancy in equilibrium. Related terms “Ec”, “Ev”, and “Ep” refer to the energy of the conduction band minimum, valence band maximum and Fermi level respectively.

“Substantially transparent” generally denotes a material or construct that does not absorb a substantial amount of light in the visible portion (and/or infrared portion in certain variants) of the electromagnetic spectrum.

“Heterojunction” refers to a junction between two different materials, independent of any doping and any crystalline differences (e.g., single crystal, polycrystalline, amorphous, etc.). In other words, an amorphous Si/single crystal Si junction would not be a heterojunction. Similarly, a B-doped Si/As-doped Si junction would not be a heterojunction. However, a CuₓS/BaCu₂S₂ junction would be a heterojunction.

“Double heterojunction” refers to a solar cell structure that includes at least two heterojunctions.

“Polycrystalline” generally refers to a material that includes many small regions (referred to as “grains”) that have different orientations of the crystal structure. A polycrystalline material should not be confused with a single crystal material or an amorphous solid.

“Solar cell” may be used interchangeably with “photovoltaic device.”

As described above, the solar cells illustrated herein typically include at least three layers. One layer is a p-type window layer made from substantially transparent material. A second layer is an n-type window layer made from substantially transparent material The third layer is an i-absorber layer, which is disposed between the p-layer and the n-layer to form the p-i-n structure. The layers typically are fabricated so that a first surface of the i-layer is contiguous with the n-layer and an opposing second surface of the i-layer is contiguous with the p-layer. A first heterojunction is present at the p-layer/i-layer interface and a second heterojunction is present at the n-layer/i-layer interface.

As described below in more detail, in one variant of the solar cell at least two of the p-, i- and n-layers are made from a Cu-containing material. In other words, the player and the i-layer are Cu materials, the i-layer and the n-layer are Cu materials, or the p-layer and the n-layer are Cu materials. According to particular examples, each one of the p-, i- and n-layers are-made from Cu-containing materials. Cu materials for the i-layer may be especially useful since a slightly p-type i-layer can be more easily fabricated from a Cu material. Cu materials for the p-layer may also be particularly beneficial since such materials can provide a high concentration of highly mobile carriers, exhibit wider bandgaps, and exhibit optical transparency. It will be apparent from the description below that “Cu-containing material” or “Cu material” refers to a material that includes Cu as at least one element in the polycrystalline structure of the material. In other words, Cu is not present in the material only as a dopant.

According to another variant of the solar cells that is described in more detail below, each of the p-, i-, and n-layers share a common anion and/or cation. By “common” anion or cation it is meant that the same cation or anion species is present in the p-layer material, the i-layer material, and the n-layer material. For example, as exemplified below in Table 1, the p-layer may be constructed from Cu-M^{II}-S, the i-layer from Cu-M^{III}-S and the n-layer from a CuS-compound. In this example, sulfur is the common anion.

The polycrystalline materials that may be used for the layers in the presently disclosed solar cells offer an optimal compromise between device performance and cost. In contrast, single crystal materials can offer a high performance, but at a high cost. Amorphous materials can offer a low cost, but result in a low performance device.

The devices constitute an optimization of materials that will work as efficient thin film solar cells. In these cells, both the p- and n-layers may be heavily doped, wide bandgap windows, whereas the i-layer may be a lightly p-doped moderate bandgap absorber.

Various elements are combined to set up n-window, p-window, and intrinsic, lightly doped, i-absorber layers in which electrons and holes are created by photoabsorption and separated for the efficient generation of electrical power. The dimensions of the thin-film solar cell layers (i.e., the total thickness of the combined p-, n-, and i-layers) can be from about 1 micron to about 5 microns.

The presently disclosed solar cells allow the elements that comprise the cells to produce electricity by setting up unfavorable recombination paths for electrons and holes, thereby improving charge separation and energy production. The double heterojunction structure can provide a built-in electric field in the i-absorber layer, yielding improved photocarrier separation; lower doping in the absorber layer, resulting in reduced photocarrier recombination in the i-absorber layer; and electron and hole ‘reflectors’ that reduce minority carrier injection and recombination. In certain embodiments, cation- and/or anion-matching of the p-, i-, and n-type layers may be employed as a means of achieving improved process integration compatibility, and hence manufacturability, as well as improved device lifetime. The presently disclosed solar cells also offer the opportunity to replace hazardous, expensive, or rare (in terms of world-wide abundance) elements utilized in present-art solar cells, e.g. Cd, In, Ga, and possibly Se, with safe and abundant substitutes.

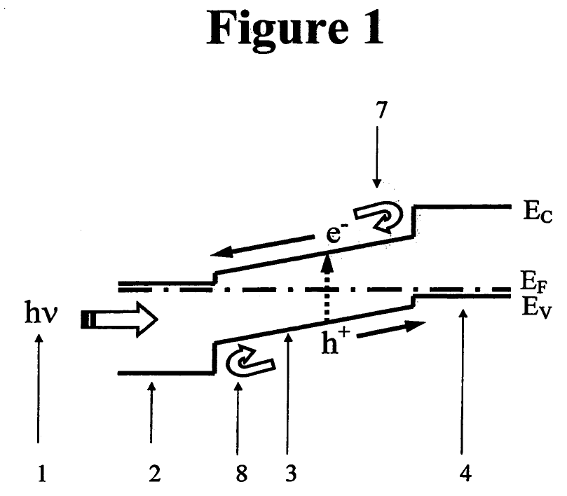

Referring now to FIG. 1, which depicts an equilibrium energy band diagram of the p-i-n double heterojunction (DHJ) portion of a thin-film solar cell; a schematic depiction of an illustrative double heterojunction configuration is shown. The figure shows light (hv) 1 entering the thin-film solar cell (TFSC) through an n-window 2 where photons are not absorbed, but move through the n-window 2 to the i-absorber 3, where photon absorption occurs. The i-layer 3 represents an intrinsic material layer, which may comprise a low-doped material as described in more detail below. The third layer in the DHJ is the p-window 4; photons are also not absorbed in this layer. In the TFSC, a reflective contact may be employed adjacent to either the n- or p-window, thereby facilitating enhanced photon absorption in the i-absorber layer as photons make a second or subsequent pass through the i-absorber layer.

It is noteworthy that the TFSC i-absorber energy bands pictured in FIG. 1 are not flat, but sloped. This is to emphasize that the electrons and holes represented by e⁻ and h⁺, respectively, are moved in the directions shown in FIG. 1 by drift motion associated with the electric field created in the TFSC i-absorber layer. As indicated by the top arrow in FIG. 1, the electrons tend to move in a downward direction to attain a lowest possible energy. The holes pictured in FIG. 1 attempt to move upwards to the right of FIG. 1, as indicated by the bottom arrow depicted. Separation of the e⁻/h⁺ pair is desired to generate electrical power.

Another noteworthy feature shown in FIG. 1 are the two open return arrows 7 and 8. These arrows indicate electron and hole ‘reflectors’ which are established by the conduction and valence band discontinuities present at the i-p and n-i interfaces (i.e., heterojunctions), respectively. The energy barriers associated with these ‘reflectors’ help suppress minority carrier injection and recombination of electrons into the p-window and holes into the n-window. Such recombination degrades the performance of a solar cell.

Yet another noteworthy feature in FIG. 1 are the notations E_{C}, B_{V}, and E_{F} which refer to the energy of the conduction band minimum, valence band maximum, and Fermi level, respectively. To those practiced in the art of semiconductor devices, the relative positions shown in FIG. 1 of E_{C} and E_{V} with respect to E_{F} indicate the relative doping densities of the respective layers and the presence of an electric field in the i-layer, as discussed previously.

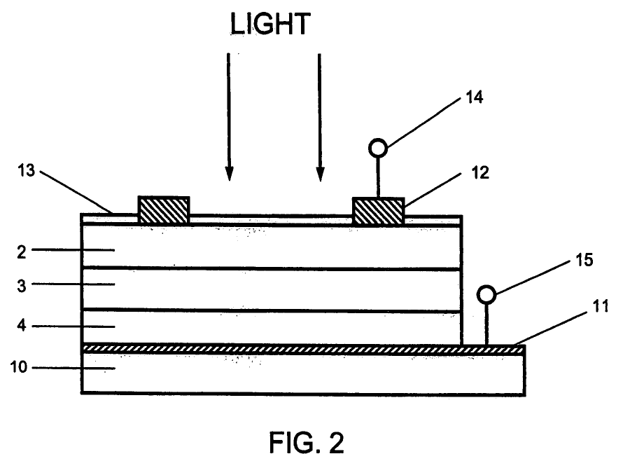

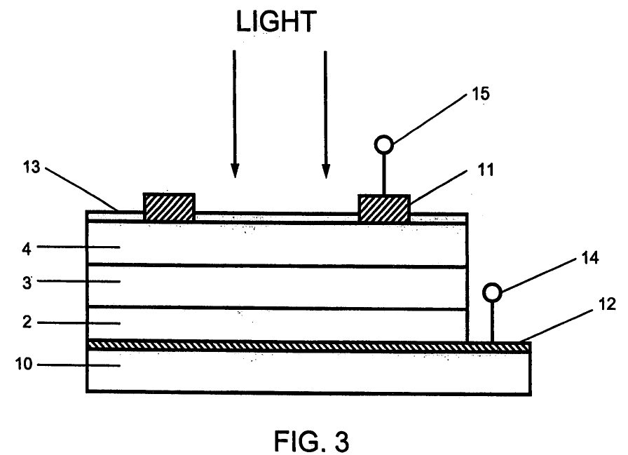

Referring now to FIG. 2, one example of a solar cell includes a substrate 10 upon which is disposed a p-type ohmic contact layer 11. An electrical connection 15 is provided to the p-type ohmic contact layer. A p-layer 4 is located between the p-type ohmic contact layer 11 and an i-layer 3. A n-layer 2 is disposed on the i-layer 3. Positioned adjacent to the n-layer 2 is an electrical current-collecting grid and n-type ohmic contact 12. An anti-reflection coating 13 is disposed on an upper surface of the n-layer 2. The anti-reflection coating may be utilized to minimize the amount of reflection off of the surface of the cell. An electrical connection 14 is provided to the electrical current-collecting grid and the n-type ohmic contact 12. Light is incident to the upper surface of the anti-reflection coating 13. FIG. 3 depicts another example of a solar cell similar to the solar cell shown in FIG. 2, except that the p-layer 4 and n-layer 2 are reversed in position.

The absorber materials that are chosen for the TFSC bandgap material (i.e., the i-layer) typically possess a direct bandgap to facilitate strong photon absorption by the i-layer absorber, thus allowing a thin absorber layer to be employer. Direct bandgap materials have a larger ambition coefficient (a) compared to indirect bandgap materials. A larger absorption coefficient means that more photons are absorbed in a layer of a given thickness. The absorber i-layer may vary in thickness, but, for example, may have a thickness of about 0.1 to about 4.0 μm. Also, the absorber may be selected to be weakly p-type, since photo-generated minority-carrier electrons invariably have a larger mobility than holes and, therefore, are more efficiently collected. In general, weakly p-type i-layer may have a hole concentration of less than about 10¹⁷/cm³, more particularly less than about 10¹⁶/cm³. The absorber is chosen to be lightly doped to maximize the minority-carrier lifetime and to facilitate the creation of a drift field so that minority carriers are efficiently extracted from the absorber, even though they possess a short minority-carrier lifetime concomitant with a direct bandgap. For instance, the i-layer may be doped so that it has a maximum majority carrier concentration of about 10¹⁷/cm³. In certain examples, the i-layer has a majority carrier concentration of about 10¹⁴/cm³ to about 10¹⁶/cm³.

Listed below in Table 1 are illustrative examples of various materials that could be used for the realization of p-i-n double-heterojunction solar cells. By using different materials in areas 2 and 4 as pictured in FIGS. 1, 2 and 3, it may be possible to increase the efficiency of the TFSC and maximize the electric power derived therefrom.

A brief summary of some of the materials that are considered for use in the p-i-n device is given in Table 1 below:

TABLE 1

| Solar Cell | | | |
|---|---|---|---|
| Type | n-Window | i-Absorber | p-Window |
| Cu-Sulfide | n-type CuS- | CuₓS, | Cu-M^{II}-S, |
| | compound | Cu-M^{II}-S, | Cu-M^{II}-S-F |
| | | Cu-M^{II}-S-F, | Cu-M^{II}-S-O |
| | | Cu-M^{II}-S-O, | Cu-M^{III}-S |
| | | Cu-M^{III}-S, | Cu-M^{III}-S-F, |
| | | Cu-M^{III}-S-F, | Cu-M^{III}-S-O |
| | | Cu-M^{III}-S-O, | Cu-M^{IV}-S |
| | | Cu-M^{IV}-S, | Cu-M^{IV}-S-F, |
| | | Cu-M^{IV}-S-F, | Cu-M^{IV}-S-O |
| | | Cu-M^{IV}-S-O | |
| Cu-Selenide | n-type CuSe- | CuInₓGa₁₋ₓSe₂, | Cu-M^{II}-Se |
| | compound | Cu-M^{II}-Se, | Cu-M^{II}-Se-F |
| | | Cu-M^{II}-Se-F, | Cu-M^{II}-Se-O |
| | | Cu-M^{II}-Se-O, | Cu-M^{III}-Se |
| | | Cu-M^{III}-Se, | Cu-M^{III}-Se-F |
| | | Cu-M^{III}-Se-F, | Cu-M^{III}-Se-O |
| | | Cu-M^{III}-Se-O, | Cu-M^{IV}-Se |
| | | Cu-M^{IV}-Se, | Cu-M^{IV}-Se-F |
| | | Cu-M^{IV}-Se-F, | Cu-M^{IV}-Se-O |
| | | Cu-M^{IV}-Se-O | |
| Cu-Telluride | n-type CuTe- | Cu₂Te, Cu-M^{II}-Te, | Cu-M^{II}-Te, |
| | compound | Cu-M^{II}-Te-F, | Cu-M^{II}-Te-F |
| | | Cu-M^{II}-Te-O, | Cu-M^{II}-Te-O, |
| | | Cu-M^{III}-Te, | Cu-M^{III}-Te, |
| | | Cu-M^{III}-Te-F, | Cu-M^{III}-Te-F, |
| | | Cu-M^{III}-Te-O, | Cu-M^{III}-Te-O |
| | | Cu-M^{IV}-Te, | Cu-M^{IV}-Te, |
| | | Cu-M^{IV}-Te-F, | Cu-M^{IV}-Te-F, |
| | | Cu-M^{IV}-Te-O. | Cu-M^{IV}-Te-O |
| Oxide | ITO*, ZnO, | CuₓO, | Cu-M^{II}-O, |
| | SnO₂ | Cu-M^{II}-O, | Cu-M^{II}-O-F, |
| | | Cu-M^{II}-O-F | Cu-M^{III}-O, |
| | | Cu-M^{III}-O, | Cu-M^{III}-O-F, |
| | | Cu-M^{III}-O-F, | Cu-M^{IV}-O |
| | | Cu-M^{IV}-O | Cu-M^{IV}-O-F |
| | | Cu-M^{IV}-O-F | |

*ITO = indium-tin oxide
Notes for Table 1:
Trivalent cations are represented by M^{III}. M^{III} may be Al, B, Sc, Y, Bi, Ti, V, Cr, In, Zr, Nb, Mo, Hf, Ta, W, the lanthanides (Er, Ho, Lu, Nd, Yb, La, Ce, Pr, Pm, Sm, Eu, Gd, Tb, Dy, Ho, Tm) and mixtures thereof.
Divalent cations are represented by M^{II}. M^{II} may be selected from Ba, Ca, Mg, Sr, Zn, Mn, Ni, Ge, Sn, Fe, Mn, Cr, V, Ti, and mixtures thereof.
Quadrivalent cations are represented by M^{IV}. M^{IV} may be selected from Ti, Zr, Hf, Nb, Ta, Mo, W, Sn, Si, C, Ge and mixtures thereof.

All of the materials listed are copper-based, except for the oxide n-windows (discussed below.) Copper can be a constituent of the TFSCs since its inclusion facilitates achieving p-type conductivity. In certain variants, the i-absorber and p-window layers are lightly and heavily p-type, respectively. For example, the i-absorber layer may have a hole concentration of less than about 10¹⁷/cm³, more particularly less than about 10¹⁶/cm³. The p-layer, on the other hand, may have a hole concentration of greater than about 1 more particularly greater than about 10¹⁸/cm³. Thus, since p-type behavior may be useful and Cu assures p-type behavior, it is present throughout Table 1.

Furthermore, as mentioned above, Cu materials for the p-layer can provide a high concentration of highly mobile carriers, exhibit wider bandgaps, and exhibit optical transparency. For example, in Cu materials for the p-layer the hole concentration can be about 10¹⁷/cm³ to about 10²¹/cm³, and hole mobility may be about 0.1 cm²V⁻¹s⁻¹ to about 20 cm²V⁻¹s⁻¹.

It is also noteworthy that Table 1 shows that all of the TFSCs have a common group 16 (oxygen, sulfur, selenium, or tellurium) anion for the p-, i-, and n-layers. This is to promote ease in process integration and long-term compatibility of the materials. With a common anion, processing steps such as annealing in an anion gas over pressure are possible at any step of the process flow. Also, common anion materials add to the compatibility of the TFSC heterojunctions because there is very little, if any, anion concentration gradient in said TFSC. Even if anion diffusion does occur, it is unlikely to lead to significant degradation in a device using a unique anion. The presently described approach does not prevent the possibility of employing dissimilar group 16 anions in two or more of the p-i-n layers of the TFSC, but the use of a common group 16 anion simplifies process integration, and it is likely to improve device stability.

The solar cell type in the fourth row of Table 1 labeled ‘Oxide’ differs from the other types specified in Table 1 since copper (Cu) is not a constituent of the oxide n-window materials. This may be an undesirable situation since a steep Cu concentration gradient will exist at the n-window/i-absorber interface, leading to possible process integration problems and device degradation as a consequence of Cu diffusion into the n-window. However, given the highly developed nature of the n-type transparent conductors specified in Table 1, as well as the emergence of new p-type transparent conductive oxides, it may be desirable to utilize oxide-based thin-film solar cells.

Several additional criteria can motivate the selection of materials, including the abundance, availability, and cost of the materials. Materials such as Au, Ga, In, Ir, Pt, and the like are less desirable since their availability and/or cost is prohibitive. The inadequate world supply of Se limits this element's applicability as well. A notable exception to this generalization is the use of Cu-selenides, including CuInₓGa₁₋ₓS₂ (CIGS), may be considered as it is a widely studied, optimized, and efficient compound used in TFSCs.

Undesirable toxic, radioactive, or otherwise hazardous materials such as Be, Cd, Hg, Pb, Tl, and the like may be used in the presently described TFSCs, but are not required. Regarding process integration, problems may arise trying to fabricate transparent heterojunction diodes using an oxide in combination with a sulfide, since proper oxide annealing requires the use of an oxide process gas whereas sulfide annealing necessitates the use of an inert gas such as argon or a reactive sulfur-containing process gas used in the annealing process. Hence, the use of a common anion may avoid these types of fabrication process integration problems.

Still further consideration is needed regarding the lifetime compatibility of TFSC materials. Certain material combinations are deemed to be inherently incompatible. For example, the fast diffusing nature of Cu results in unacceptable degradation in conventional CdS/CuₓS solar cells and electroluminescent devices. Thus, care is taken in materials selection to avoid these types of inherently unreliable materials combinations.

Strongly p-type thin-films of CuScO₂₊ₓ have recently been prepared to develop new p-type transparent conductors. Two types of p-doping strategies have been utilize; Mg substitutional acceptor doping and oxygen intercalation (denoted as O₂₊ₓ). Such p-type doping results in blackening of the thin film layer, indicating that these films are strongly absorbing in the visible portion of the electromagnetic spectrum. Optimization of CuScO₂₊ₓ thin-films for i-absorber applications may be done by maximizing the blackening of weakly p-type layers.

CuSc-sulfide, selenide, and telluride are of possible use as a constituent of the TFSC. Since Sc is trivalent and has an octahedral ionic radius of 88.5 pm, it is a potentially useful substitute for In which is also trivalent and has an ionic radius of 94 pm. Furthermore, the price of Sc appears to be largely determined by its current lack of commercial application, and may be available at a moderate cost if an appropriate commercial market were to emerge. Still further, it has been reported that CuScS₂ has an indirect bandgap of 1.8 eV. It appears that CuScS₂, CuScSe₂ and CuScTe₂, may be appropriate for Cu-based n-window applications.

CuSn-sulfide, selenide, and telluride fluorides are possible p- or n-type transparent conductors for use in the presently disclosed cells. For example, BaCuSF has been found to exhibit a band gap near 3.1 eV, and conductivities near 100 S cm⁻¹ have been observed in pressed pellets. Like other CuS-based transparent conductors examined, this material provides unique opportunities in processing at relatively low temperatures (T<623 K.) Doped sulfide fluorides containing both Cu and Sn with relatively high Sn concentrations may lead to n-type conductivity.

A further example of a useful material for an optically transparent p-layer is BaCu₂S₂, particularly a low-temperature orthorhombic crystal form. A layer of BaCu₂S₂ may be provided on a substrate surface by initially preparing a powder by heating a stoichiometric mixture of the reagents BaCO₃ and Cu₂S at 923 K for 1 hour under flowing H₂S(g) and then cooling to room temperature under flowing Ar (g). A 50-cm diameter, sintered disk is then fabricated by pressing a powder at 4 tons and annealing at 1048 K for 5 hours in an Ar atmosphere. Thin films are deposited onto appropriate substrates by using the fabricated disk and RF sputtering with a gas mixture of Ar/He (60% /40%) at 35 mTorr and 80 sccm. During deposition, the substrate is maintained at an appropriate temperature (T≈573 K) to promote film adhesion. Such materials are described in more detail in Park et al., “Transparent p-type conducting BaCu₂S₂ films,” Applied Physics Letter, 80:4393, 2002.

SrCu₂O₂ and LaCuOS are two other specific examples of possible optically transparent p-layer materials.

Materials containing Cu and Sn are also of particular interest. Controlled doping of compounds rich in Cu, such as Cu₄SnS₄, leads to p-type conductivity and application in the p-layer and the i-layer. Controlled doping of compounds rich in Sn, such as CuSn_{3.75}S₈, leads to n-type conductivity and application in the n-layer. Compositions containing equivalent concentrations of Cu and Sn, such as SrCu₂Sn₂S₆, SrCu₂Sn₂S₄F₄, and SrCu₂Sn₂S₄O₂, can be selectively doped to produce either p-type or n-type conductivity, providing application in each of the p-layer, i-layer, and n-layer. The Sr cation can be replaced according to the classifications in Table 1; similarly, the anions oxide, fluoride, and sulfide can be replaced by other anions as set forth by the prescriptions of Table 1.

The bandgaps of the player material and n-layer material may vary depending upon the application of the solar cell. Wider bandgap material for the p-layer will provide a greater electron reflective effect at the p-layer/i-layer heterojunction. Similarly, wider bandgap material for the n-layer will provide a greater hole reflective effect at the n-layer/i-layer heterojunction. Although the bandgaps can vary considerably, in general, the bandgap for the p- or n-layer may range from about 2 eV to about 4 eV for single-junction solar cell arrangements, about 1 eV to about 4 eV for multi-junction solar cell arrangements, and from about 1 eV to about 2 eV for thermophotovoltaic solar cell arrangements.

In selected variants, the p-layer material and the n-layer material may be heavily doped to provide a minimum respective carrier concentration of about 10¹⁸/cm³. According to more specific examples, the p-layer material and the n-layer material may each have a respective carrier concentration of about 10¹⁹/cm³ to about 10²¹/cm³.

Doping, either p- or n-type, may be achieved by extrinsic substitutional acceptor or donor doping, intrinsic naive defect doping, or oxygen intercalation (denoted as O₂₊ₓ). Substitutional acceptor doping typically may be accomplished by selecting a cation (anion) dopant with a valence one less than the cation (anion) for which it substitutes. Thus, a column 1 atom substituting for a column 2 cation, or a column 15 atom substituting for a column 16 anion will, in general, give rise to extrinsic acceptor doping. Similarly, substitutional donor doping is typically accomplished by selecting a cation (anion) dopant with a valence one greater than the cation (anion) for which it substitutes. Thus, a column 13 atom substituting for a column 2 cation, or a column 17 atom substituting for column 16 anion will, in general, give rise to extrinsic donor doping. In contrast intrinsic native doping usually involves either vacancies or interstitials of the atomic constituents comprising the material. For example, a cation vacancy (e.g. a Cu-vacancy in BaCu₂S₂) is an acceptor, giving rise to p-type doping, while an anion vacancy (e.g. an O-vacancy in ZnO) is a donor, giving rise to n-type doping. Oxygen intercalation doping involves processing the oxide material in such a way that more oxygen is incorporated into the layer than required to achieve full stoichiometry; essetislly, this incorporated excess oxygen acts as an interstitial acceptor dopant, rendering the material p-type. Typically, doping of these p-, i-, or n-layers is accomplished either during the deposition of each layer, or via post-deposition annealing. Additionally, doping via solid-state diffusion or ion implantation could be employed.

In general, the TFSCs may be fabricated by first providing a substrate for supporting the films. “Substrate,” as used herein refers to the physical object that is the basic workpiece that is transformed by various process operations into the desired microelectronic configuration. A substrate may also be referred to as a wafer. Wafers may be made of semiconducting, non-semiconducting, or combinations of semiconducting and non-semiconducting materials. The substrate may be made from any suitable material. The substrate material is optionally an opaque material or a substantially transparent material illustrative substrate materials include glass, silicon, plastic and thin metal sheets. The thickness of the substrate may vary, and according to particular examples it can range from about 100 μm to about 1 cm.

Each of the p-, i-, and n-layers can be formed by depositing the desired material onto a surface. Deposition can be accomplished, for example, via sputtering (e.g., RF sputtering), electron beam evaporation, thermal evaporation, chemical bath deposition or chemical vapor deposition The p-, i-, and n-layers can be deposited in order, provided the i-layer is interposed between the p- and n-layers. Either the n-layer or the p-layer may be deposited onto the support substrate. The i-layer then is deposited onto the n-layer or the player. The layer that has not yet been deposited (i.e., the n-layer or the player) then is deposited onto the i-layer.

In the case of RF sputtering, sintered targets for film deposition may be prepared using various techniques. An example of such a technique is described above in connection with BaCu₂S₂. The deposited layers and/or sintered targets may be annealed to obtain polycrystalline films with the desired characteristics. The annealing time may vary depending upon the compound, but may range, for example, from about 1 minute to about 30 minutes. The annealing temperature also may vary. For example, with respect to both the sintered targets and the layer, the temperature may range from about 200° C. to about 800° C. The annealing may be performed in any suitable atmosphere such as, for example, Ar, sulfur(g), O₂, air and mixtures thereof. An annealing process may be performed after each layer is deposited. Alternatively, the annealing may be performed only after a plurality of layers have been deposited.

Since process technologies, such as rapid-thermal annealing can be typically used to fabricate the TFSCs illumed herein, the p-i and n-i heterojunctions may be compositionally-graded over a dimension of ˜10 mm so that conduction or valence band spikes are washed out and, to first order, the energy bands are expected to be similar to those shown in FIG. 1. In other words, rather than an abrupt material boundary line at a heterojunction, the annealing results in a region where the composition structure more gradually changes from one material to the other as viewed in the vertical direction of the structure.

Electrical contact to the n-layer, p-layer and substrate, as desired, may be provided in any manner. For example, metal lines, traces, wires, interconnects, conductors, signal paths and signaling mediums may be used for providing the desired electrical connections. The related terms listed above, are generally interchangeable, and appear in order from specific to general. Metal lines, generally aluminum (Al), copper (Cu) or an alloy of Al and Cu, are conductors that provide signal paths for coupling or interconnecting, electrical circuitry. Conductors other than metal may also be utilized.

The solar cells disclosed herein may be useful in a variety of applications. For example, the solar cells may be employed in a multifunction configuration in which two, three, or four semiconductor solar cells with differing bandgaps matched to different portions of the solar spectrum are stacked in tandem in order to absorb a larger fraction of the total solar spectrum. Another option is to use the cells for thermophotovoltaic purposes in which thermal radiative energy, rather than solar energy, is converted to electricity. Optimal semiconductor bandgaps for obtaining high conversion efficiencies are approximately in the 0.5 to 0.6 eV range.

Having illustrated and described the principles of the disclosed structures and methods with reference to several examples, it should be apparent that these methods and structures may be modified in arrangement and detail without departing from such principles.

1. A thin-film solar cell comprising a p-i-n double heterojunction structure that includes a polycrystalline p-layer, a polycrystalline i-layer, and a polycrystalline n-layer, wherein at least two of the player, i-layer, and n-layer comprise a polycrystalline Cu material.

2. The solar cell of claim 1, wherein the player, i-layer, and n-layer each comprise a polycrystalline Cu material.

3. The solar cell of claim 1, wherein the i-layer comprises an absorber layer, and the p-layer and the n-layer each comprise a window layer.

4. The solar cell of claim 1, wherein the i-layer has a maximum majority carrier concentration of about 10¹⁷/cm³.

5. The solar cell of claim 1, wherein the i-layer has a majority carrier concentration of about 10¹⁴/cm³ to about 10¹⁶/cm³.

6. The solar cell of claim 4, wherein the p-layer and the n-layer each have a minimum respective carrier concentration of about 10¹⁸/cm³.

7. The solar cell of claim 5, wherein the p-layer and the n-layer each have a respective carrier concentration of about 10¹⁹/cm³ to about 10²¹/cm³.

8. The solar cell of claim 1, wherein the player is produced by annealing, the i-layer is produced by annealing, and the n-layer is produced by annealing.

9. The solar cell of claim 1, wherein each of the player, i-layer, and n-layer further comprise a common cation or a common anion in addition to Cu.

10. The solar cell of claim 9, wherein each of the player, i-layer, and n-layer comprise a common anion.

11. The solar cell of claim 1, wherein the n-layer is selected from a copper sulfide compound, a copper selenide compound, a copper telluride compound, an indium tin oxide compound, a zinc oxide compound, a tin oxide compound, and mixtures thereof.

12. The solar cell of claim 11, wherein the n-layer comprises a copper sulfide compound, and the i-layer is selected from a copper sulfide compound, a divalent metal copper sulfide compound, a divalent metal copper sulfide fluoride compound, a divalent metal copper sulfide oxide compound, a trivalent metal copper sulfide compound, a trivalent metal copper oxide sulfide compound, a trivalent metal copper sulfide fluoride compound, a quadrivalent metal copper sulfide compound, a quadrivalent metal copper sulfide oxide compound, a quadrivalent metal copper sulfide fluoride compound and mixtures thereof.

13. The solar cell of claim 12, wherein the p-layer is selected from a divalent metal copper sulfide compound, a divalent metal copper sulfide fluoride compound, a divalent metal copper sulfide oxide compound, a trivalent metal copper sulfide compound, a trivalent metal copper oxide sulfide compound, a trivalent metal copper sulfide fluoride compound, a quadrivalent metal copper sulfide compound, a quadrivalent metal copper sulfide oxide compound, a quadrivalent metal copper sulfide fluoride compound and mixtures thereof.

14. The solar cell of claim 11, wherein the n-layer comprises a copper selenide compound and the i-layer is selected from a copper indium gallium diselenide compound, a copper divalent metal selenide compound, a copper divalent metal selenide fluoride compound, a copper divalent metal selenide fluoride compound, a copper divalent metal selenide oxide compound, a copper trivalent metal selenide compound, a copper trivalent metal selenide fluoride compound, a copper trivalent metal selenide oxide compound, a copper quadrivalent metal selenide compound, a copper quadrivalent metal selenide fluoride compound, a copper quadrivalent metal selenide oxide compound, and mixtures thereof.

15. The solar cell of claim 14, wherein the p-layer is selected from a copper divalent metal selenide compound, a copper divalent metal selenide fluoride compound, a copper divalent metal selenide oxide compound, a copper trivalent metal selenide compound, a copper trivalent metal selenide fluoride compound, a copper trivalent metal selenide oxide compound, a copper quadrivalent metal selenide compound, a copper quadrivalent metal selenide fluoride compound, a copper quadrivalent metal selenide oxide compound and mixtures thereof.

16. The solar cell of claim 11, wherein the n-layer comprises a copper telluride compound and the i-layer is selected from a copper telluride compound, a copper divalent metal telluride compound, a copper divalent metal telluride fluoride compound, a copper divalent metal telluride oxide compound, a copper trivalent metal telluride compound, a copper trivalent metal telluride fluoride compound, a copper trivalent metal telluride oxide compound, a copper quadrivalent metal telluride compound, a copper quadrivalent metal telluride fluoride compound, a copper quadrivalent metal telluride oxide compound and mixture thereof.

17. The solar cell of claim 16, wherein the player is selected from a copper divalent metal telluride compound, a copper divalent metal telluride fluoride compound, a copper divalent metal telluride oxide compound, a copper trivalent metal telluride compound, a copper trivalent metal telluride fluoride compound, a copper trivalent metal telluride oxide compound, a copper quadrivalent metal telluride compound, a copper quadrivalent metal telluride fluoride compound, a copper quadrivalent metal telluride oxide compound and mixtures thereof.

18. The solar cell of claim 11, wherein the n-layer is selected from indium tin oxide, zinc oxide, and tin oxide.

19. The solar cell of claim 18, wherein the i-layer is selected from a copper oxide compound, a copper divalent metal oxide compound, a copper divalent metal oxide fluoride compound, a copper trivalent metal oxide compound, a copper trivalent metal fluoride compound, a copper quadrivalent oxide compound, a copper quadrivalent oxide fluoride compound and mixtures thereof.

20. The solar cell of claim 19, wherein the p-layer is selected from a copper divalent metal oxide compound, a copper divalent metal oxide fluoride compound, a copper trivalent metal oxide compound, a copper trivalent metal oxyfluoride compound, a copper quadrivalent oxide compound, a copper quadrivalent oxide fluoride compound and mixtures thereof.

21. The solar cell of claim 1, wherein the combined thickness of the p-layer, i-layer, and n-layer is about 1 to about 5-microns.

22. The solar cell of claim 10, wherein the n-, i- and p-layers each comprise a common anion selected from oxygen, sulfur, selenium and tellurium.

23. The solar cell of claim 22, wherein the n-, i- and p-layers each comprise a common anion selected from oxygen and sulfur.

24. The solar cell of claim 1, wherein at least the i-layer and the p-layer comprise a Cu material.

25. A thin-film solar cell comprising a p-i-n double heterojunction structure that includes a polycrystalline player, a polycrystalline i-layer, and a polycrystalline n-layer, wherein each of the p-layer, i-layer, and n-layer comprise a common cation or a common anion.

26. The solar cell of claim 25, wherein each of the player, i-layer, and n-layer comprise a common cation.

27. The solar cell of claim 25, wherein each of the player, i-layer, and n-layer comprise a common anion.

28. The solar cell of claim 27, wherein the n-, i- and p-layers each comprise a common anion selected from oxygen, sulfur, selenium, and tellurium.

29. The solar cell of claim 28, wherein the n-, i- and p-layers each comprise a common anion selected from oxygen and sulfur.

30. The solar cell of claim 12, wherein the n-layer comprises MCu₂S₂ or MCuSF, wherein M is selected from Ca, Sr, Ba or mixtures thereof.

31. A method for making a thin-film solar cell, comprising:
depositing a p-type material, an intrinsic material, and a n-type material onto a substrate so as to form a p-i-n double heterojunction structure; and
annealing the p-type material, intrinsic material, and n-type material to produce a polycrystalline p-layer, a polycrystalline i-layer, and a polycrystalline n-layer, wherein at least two of the p-type layer, the intrinsic layer, and the n-type layer comprise a Cu material.

32. An electrical current generating system comprising at least one solar cell according to claim 1.

33. An electrical current generating system comprising at least one solar cell according to claim 25.
